(19) United States
(12) Patent Application Publication
(10) Pub. No.: US 2020/0091881 A1
(43) Pub. Date: Mar. 19, 2020

(54) DIFFERENTIAL TRANS-IMPEDANCE AMPLIFIER

(71) Applicant: Elenion Technologies, LLC, New York, NY (US)

(72) Inventors: Daihyun Lim, Edgewater, NJ (US); Alexander Rylyakov, Staten Island, NY (US)

(21) Appl. No.: 16/551,867

(22) Filed: Aug. 27, 2019

Related U.S. Application Data
(63) Continuation-in-part of application No. 16/135,914, filed on Sep. 19, 2018, now Pat. No. 10,498,461.

(51) Int. Cl. H03F 3/45; H03F 3/183; H03F 3/10

(52) U.S. Cl. CPC H03F 3/45076; H03F 3/10; H03F 3/183

(57) ABSTRACT

In conventional high data rate receivers, the transmitted optical signal has poor extinction ratio and translates into a small modulated current with a large DC current, which saturates the receiver TIA and amplifiers, and significantly degrades the gain and bandwidth performance. Consequently, cancelling PD DC current in high data rate receivers is desired for proper operation. Differential TIA schemes, i.e. providing separate AC-coupled and DC-coupled paths, in parallel, provide better linearity for large input currents and low gain settings. To AC couple the PD to the TIA using passive AC-coupling circuitry, an AC-coupling capacitor (C_{C}) is positioned between the PD and the TIA to block the DC current, while passing the modulated AC current to the TIA. A DC cancellation circuit may be provided, without a capacitor, to maintain the receiver input bias while suppressing any DC component generated by the PD for the DC-coupled path.

### CROSS REFERENCE TO RELATED APPLICATIONS

This application is a continuation-in-part of and claims priority from U.S. patent application Ser. No. 16/135,914, entitled Optical Receivers with DC Cancellation and Offset Cancellation, filed Sep. 19, 2018, which is incorporated herein by reference.

### TECHNICAL FIELD

The present invention relates to a trans-impedance amplifier (TIA) for a photodetector circuit, and in particular to a differential TIA with a mixed AC/DC coupling scheme.

### BACKGROUND

A typical optical receiver front-end is composed of a photo diode (PD) 1 followed by a trans-impedance amplifier (TIA) 2 and main voltage amplifiers (MAs) 3 as shown in FIG. 1. The PD 1 receives a transmitted optical signal 4 and generates a PD output current 6 proportional to the received optical power of the transmitted optical signal 4. The ratio between PD output current 6 to the input optical power of the optical signal 4 is the photo diode responsivity (R). The TIA 2 converts the PD output current 6 to a voltage, which is then amplified by the MAs 3 to the desired signal level for the decision circuitry 7. For NRZ modulation, the modulation depth of the transmitted optical signal 4 is defined by its extinction ratio, which is the ratio between optical power for symbol one (P₁) and optical power for symbol zero (P₀). In high data rate receivers, the transmitted optical signal 4 has poor extinction ratio and translates into a small modulated current with a large DC current at the output of the photo diode 1. The large DC current saturates the receiver front-end, i.e. the TIA 2 and the MAs 3, and significantly degrades the gain and the bandwidth performances. Consequently, cancelling the photo diode DC current in high data rate receivers is desired for proper receiver operation, i.e. to have zero average modulated PD current 6.

Moreover, for coherent optical communication links, mixing local laser power and the modulated transmitted optical signal 4 using the photo diode 1 results in very large DC current. PD DC current is expressed as,

I_{DC}=R×(P_{LO}+P_{S}), (1)

where P_{LO} is the local optical laser power and P_{S} is the received optical signal power. Equation (1) shows that the photo diode output DC current of the PD 1 in coherent optical communication links depends on the local laser power and the optical received power. For example, a photo diode 1 with responsivity (R) of 1 A/W results in 4 mA DC current at 6 dBm local laser power input. Such a large DC current is more than enough to saturate the receiver front-end and severely degrade performance. Thus, it is very important to have DC current cancellation circuitry in front of the TIA 2 of coherent optical communication links.

FIG. 2 illustrates a conventional way to AC couple a receiver photo diode 11 to a front-end TIA 12 using passive AC coupling circuitry. AC coupling capacitors (C_{C}) are inserted between the photo diode 11 and the front-end TIA 12 to block the DC current; while bypassing the modulated AC current to the TIA 12. A biasing resistor (R_{C}) is used to bias the photo diode anode voltage to be reverse biased, and provides an alternative path for the photo diode DC current I_{DC}. The biasing resistor R_{C} with the AC coupling capacitor C_{C} forms a high pass filter section in the RF signal path, whereby a cutoff frequency (FC) is calculated as,

$${F}_{C} = \frac{1}{2 π {R}_{C} {C}_{C}} \qquad ( 2 )$$

However, for the latest photodetectors the required TIA low cutoff frequency (FC) is around 1 MHz which requires either a large AC coupling capacitor C_{C} or a huge biasing resistor R_{C}. As an example, a coupling capacitor C_{C} with a capacitance of at least 1.6 pF with a biasing resistor R_{C} with a resistance of at least 1 MΩ are required to achieve cutoff frequency of 1 MHz. Unfortunately, this technique suffers from two main drawbacks: 1) C_{C} parasitic capacitance, and 2) photo diode biasing. For bulk silicon technologies, the bottom plate ground parasitic capacitance of the coupling capacitor C_{C} is around 10% of its value and degrades the front-end TIA bandwidth, which is defined by its input node capacitance. Thus, there is a maximum coupling capacitor (C_{C}) that can be used without degrading the TIA bandwidth. On the other hand, the biasing voltage across the photo diode 11 is defined by the following equation:

V_{BIAS}=V_{PD}−2(I_{DC}×R_{C}), (3)

where V_{BIAS} is the reverse bias voltage across the photo diode PN junction, V_{PD} is the bias supply voltage for the photo diode 11, and I_{DC} is the DC current (average current) through the photo diode 11. High photo diode reverse biasing voltage is required to obtain good photo diode responsivity and low PN junction capacitance. However, equation (3) shows that V_{BIAS} depends on PD average current and leads to different PD biasing for different received optical power. Furthermore, a large R_{C} value impedes receiving high optical power levels as the DC current will be large and the voltage drop across the biasing resistor R_{C} will be huge. As a numerical example, an I_{DC} of 10 μA leads to a 10 V drop on a 1 MΩ biasing resistor R_{C}, which is not practical. Moreover, the situation in coherent optical receivers is much worse as the photo diode DC current is around 1 mA and requires a biasing resistor R_{C} of less than 1 kΩ for less than 1 V drop across the biasing resistor R_{C}.

An object of the present invention is to overcome the shortcomings of the prior art by providing a differential TIA scheme with mixed DC and AC coupling to provide a desired low cut off frequency with low noise.

### SUMMARY OF THE INVENTION

Accordingly, the present invention relates to an optical receiver comprising:

a photodetector configured to generate a differential input current including a first input current component and a second input current component in response to an optical signal;

a trans-impedance amplifier (TIA) comprising a first TIA section and a second TIA section, the first TIA section configured to convert the first input current component into a first input voltage component, and the second TIA section configured to convert the second input current component into a second input voltage component;

variable gain amplifier (VGA) configured to amplify the first input voltage component and the second input voltage component to a desired output voltage forming a first output voltage component and a second output voltage component;

an AC coupler in an AC-coupled path for AC coupling the first TIA section to the photodetector; and

a DC coupler in a DC-coupled path, absent a capacitor, for DC coupling the second TIA section to the photodetector.

### BRIEF DESCRIPTION OF THE DRAWINGS

The invention will be described in greater detail with reference to the accompanying drawings which represent preferred embodiments thereof, wherein:

FIG. 1 is a schematic diagram of a conventional photodetector circuit;

FIG. 2 is a schematic diagram of a conventional differential photodetector circuit with AC coupling;

FIG. 3 is a schematic diagram of a differential photodetector circuit with a mixed coupling scheme in accordance with an exemplary embodiment of the present invention;

FIG. 4 is a schematic diagram of the differential photodetector circuit of FIG. 3, with a DC cancellation circuit;

FIG. 5A is a schematic diagram of a shunt feedback TIA for the DC coupled path; and

FIG. 5B is a schematic diagram of a shunt feedback TIA for the AC coupled path.

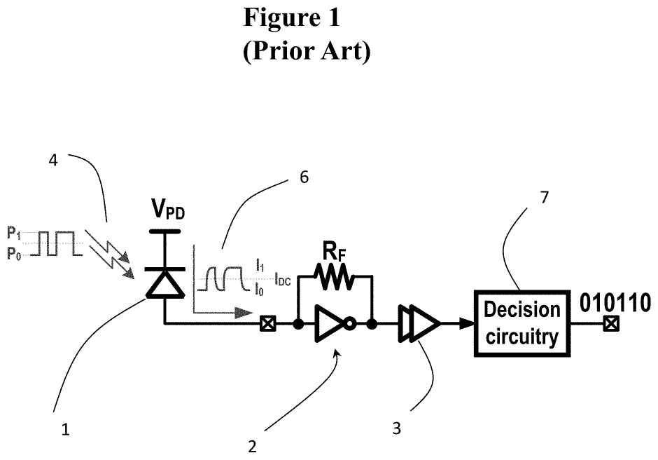

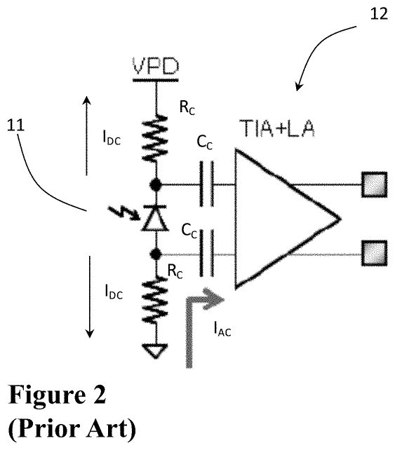

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art.

Compared to the above described single-ended schemes, a differential TIA scheme has advantages because the differential signal becomes 2× larger, while the RMS added random noise is only √2× larger, and therefore the differential TIA has increased SNR by only √2×. Moreover, differential TIA schemes provide better linearity for large input currents and low gain settings due to better common mode rejection ratio (CMRR) by 2^{nd} harmonics rejection. Improved linearity is critical in PAM4 or higher order modulation schemes.

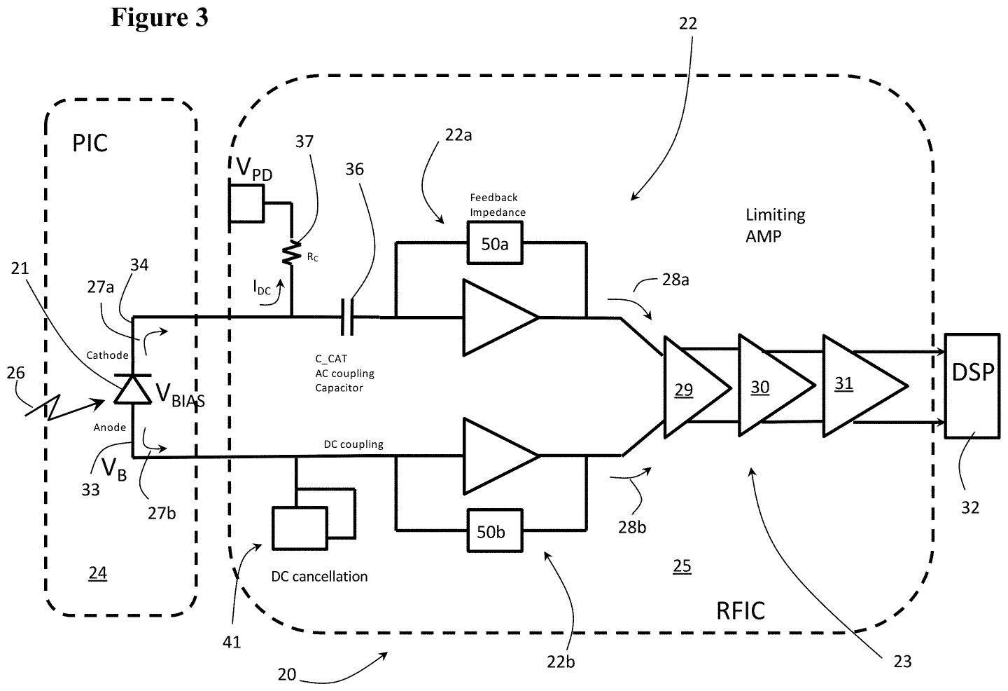

With reference to FIG. 3, an optical receiver 20, in accordance with the present invention, comprises of a photodetector, e.g. photo diode (PD), 21 followed by a trans-impedance amplifier (TIA) 22 and main voltage amplifiers (MAs) 23. The PD 21 and the TIA 22 may be disposed on separate integrated circuit chips, e.g. photonic integrated circuit (PIC) 24 and an RF integrated circuit (RFIC) 25, respectively. The PD 21 receives a transmitted optical signal 26, and generates a differential current signal comprised of a first current component 27a and a second current component 27b, proportional to the received optical power of the transmitted optical signal 26. The trans-impedance amplifier (TIA) 22 may be comprised of a first TIA section 22a and a second TIA section 22b, each of the first and second TIA sections 22a and 22b are configured for converting one of the first and second current components 27a and 27b, respectively, of the differential current signal into a differential voltage signal comprising a first voltage component 28a and a second voltage components 28b. The MAs 23 may include one or more of a variable gain amplifier (VGA) 29 configured for amplifying the first and second components 27a and 27b of the voltage signal, a limiting amplifier 30 for attenuating the first and second components 27a and 27b of the voltage signal, and a driver stage 31 for driving subsequent stages, e.g. an ADC. The PD 21 may be provided on the separate photonic integrated circuit (PIC) 24 including one or more transducers, such as one or more photodetectors 21 or on the same IC 25 as the remainder of the optical receiver 20. The back end of the optical receiver 20 may be connected to an output load, e.g. a digital signal processor (DSP) 32 for converting the output of the optical receiver 20 into digital signals.

The PD 21 includes an anode 33 and a cathode 34, which are coupled to two different paths, i.e. an DC-coupled signal path and a AC-coupled signal path, respectively. To AC couple the PD 21 to the TIA 22 using passive AC-coupler circuitry, an AC-coupling capacitor (C_{C}) 36 is positioned between the photodetector 21 and the TIA 22 to block the DC current, while passing the modulated AC current to the TIA 22. A biasing resistor (R_{C}) 37 extending from the AC-coupled path to a biasing voltage source V_{PD} is used to bias the voltage from the cathode 34 to be reverse biased, and provides an alternative path for the photo diode DC current I_{DC}. The biasing resistor R_{C} 37 with the AC-coupling capacitor C_{C} 36 form a high pass filter section in the RF AC-coupled signal path, whereby the cutoff frequency (F_{C}) is calculated as,

$${F}_{C} = \frac{1}{2 π {R}_{C} {C}_{C}} \qquad ( 4 )$$

However, the latest photodetectors require a TIA low cutoff frequency (F_{C}) around 1 MHz, which requires either a large AC coupling capacitance C_{C} or a huge biasing resistance R_{C}. As an example, a coupling capacitor 36 with a coupling capacitance C_{C} of 4 pF would require a biasing resistor 37 with a biasing resistance R_{C} of at least 40 kΩ to achieve cutoff frequency of 1 MHz, resulting in a photodiode biasing voltage of over 20V for 0.5 mA of input current, which is unacceptable. As stated above, this technique also suffers from two main drawbacks: 1) parasitic capacitance, and 2) photo diode biasing. For bulk silicon technologies, the bottom plate ground parasitic capacitance of the coupling capacitor 36 is around 10% of its value and degrades the bandwidth of the front-end of the TIA 22, which is defined by its input node capacitance. Thus, there is a maximum coupling capacitance C_{C} for the coupling capacitor 36 that can be used without degrading the bandwidth of the TIA 22. Accordingly, a coupling capacitance C_{C} of less than 10 pF, preferably less than 6 pF, and more preferably between 2 pF and 5 pF is preferred for the coupling capacitor 36 as an AC coupler for the AC-coupled path. A resistance of less than 10 kΩ, preferably less than 6 kΩ, and more preferably between 2 kΩ and 5 kΩ may be used as R_{C} in the biasing resistor 37 in the AC coupler for the AC-couple path.

However, to further reduce and control the V_{BIAS}, the anode voltage V_{B} from the DC coupling path may be preset, as hereinafter described, whereby the biasing voltage across the photodetector 21 is defined by the following equation:

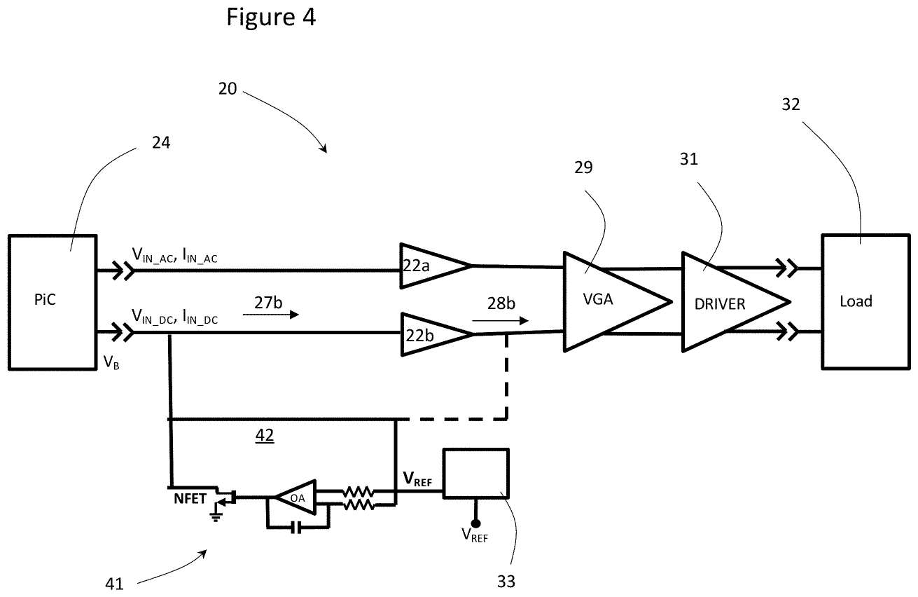

V_{BIAS}=V_{PD}−V_{B}−(I_{DC}×R_{C}), (5)

where V_{BIAS} is the reverse biasing voltage across the PN junction of the photodetector 21, V_{PD} is the photodiode bias voltage from a bias voltage source, I_{PD} is the DC current (average current) through the photodetector 21 caused by the incoming light, and V_{B} is the voltage from Anode 33 or the TIA input voltage, as will be discussed below with reference to FIG. 4. The photodiode bias voltage V_{PD} may be between 2 volts and 6 volts, preferably about 4 volts. A high photo diode reverse biasing voltage V_{BIAS} is required to obtain good photo diode responsivity and low PN junction capacitance. However, equation (5) shows that V_{BIAS} depends on PD average current (I_{DC}) and leads to different PD biasing for different received optical power. Furthermore, a large resistance R_{C} value in the biasing resistor 37 impedes receiving high optical power levels as the DC current I_{DC} will be large and the voltage drop across the biasing resistor 37 will be huge. As a numerical example, a DC current I_{DC} of 10 μA leads to a 10 V drop on a 1 MΩ biasing resistance R_{C} for the biasing resistor 37, which is not practical. Moreover, the situation in coherent optical receivers is much worse as the photodiode DC current I_{DC} is approximately 1 mA and requires a biasing resistance R_{C} of less than 1 kΩ for less than a 1 V drop across the biasing resistor 37.

With reference to FIG. 4, a DC cancellation circuit 41 may be provided as a DC coupler, in the absence of a coupling capacitor, to maintain the receiver input bias while suppressing any DC component at the input generated by the PD 21 for the DC-coupled path, as disclosed in U.S. patent application Ser. No. 16/135,914, entitled Optical Receivers with DC Cancellation and Offset Cancellation, filed Sep. 19, 2018, which is incorporated herein by reference. The DC cancellation circuit 41 uses a closed loop 42 in which a sample voltage or current is compared to a reference voltage (or current) V_{REF}. V_{REF} may be the optimum input bias for the TIA 22, and therefore depends on the TIA circuit topology. Typically, V_{REF} may be 0.3V to 1.5V, and ideally about 1V, but other TIA designs may utilize a V_{REF} above or below these values. V_{REF} is an on-chip (or off-chip) reference voltage that may be designed to be invariant, e.g. bandgap voltage, or have a temperature or process dependency. The closed loop 42 may be used to define the output or the input bias condition. The reference voltage V_{REF} may be generated by a replica TIA with open input. The reference voltage (or current) V_{REF} is selected to guarantee proper operation of the receiver 20. DC cancellation circuit (DCCC) sensing points for the DC cancellation circuit 41 may be positioned before the second TIA section 22b enabling the DC cancellation circuit 41 to sample the second current component 27b or after the second TIA section 22b enabling the DC cancellation circuit to sample the second voltage component 28b.

In the DC cancellation circuit 41, the reference voltage signal V_{REF} is compared in a voltage comparator OA with one of the sensing input points, e.g. taken at the input or the output of the second TIA section 22b generating a comparison. The difference, i.e. the comparison, between the sensed point and the modified reference voltage signals V_{REF} is used to control a first terminal, e.g. gate, of a first feedback transistors, e.g. N_{FET}, to sink the input DC current of the second current component 27b (I_{IN_DC}) of the DC-coupled path via the second and third terminals, e.g. drain and source, of the feedback transistor N_{FET}, and set the DC input voltage (V_{B}) V_{IN_DC} for the second TIA section 22b to be about equal to V_{REF}, e.g. 0.3 V to 1.5 V, preferably 0.6 V to 1.1 V.

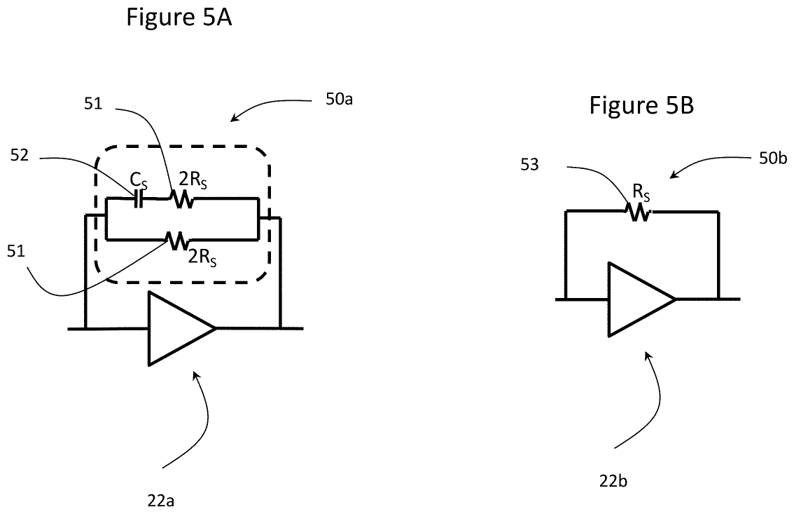

Due to the limited time-constant from the biasing resistance R_{C} of the biasing resistor 37 and the capacitance C_{C} of the coupling capacitor 36 in the AC-coupled path, the low cut-off frequency (F_{C}) may be higher than the link specification (˜1 MHz). However, a low frequency gain boosting of the impedance in the shunt-feedback of the first TIA section 22a in the AC-coupled path may resolve this problem. With reference to FIG. 5A, a first shunt feedback impedance 50a for the first TIA section 22a may be comprised of two, parallel shunt feedback resistors 51 in top and bottom paths, with a feedback capacitor 52 with capacitance C_{S} in series with one of the shunt feedback resistors 51, e.g. in top path. With reference to FIG. 5B, a typical TIA section, e.g. the second TIA section 22b, includes a second shunt feedback impedance 50b, based on a single shunt feedback resistor 53 with resistance R_{S}. Each of the parallel shunt feedback resistors 51 may comprise approximately twice the shunt feedback resistance 2R_{S} of the feedback resistor 53 of the second shunt feedback impedance 50b in the second TIA section 22b in the DC-coupled path Whereby, below the RC cut-off frequency, the feedback capacitor 52 of the top path (F_{C}˜=1/(2πC_{S}2R_{S})) is open, the TIA gain is twice the normal gain due to the doubling of the shunt-feedback resistance (2×R_{S}) of the bottom path. Whereby, above a desired threshold, e.g. the RC cut-off frequency F_{C}, the feedback capacitor 52 is closed, the effective overall resistance is the same as the second TIA section 22b, i.e. two resistors in parallel: R_{S} (½R_{S}+½Rₛ=1/R_{S}), and the high frequency gain, e.g. above the cut-off frequency F_{C}, is the same as in the second TIA section 22b. A shunt feedback resistance R_{S} of between 500Ω and 1000Ω may be used, with a feedback capacitance C_{S} of between 5 pF and 10 pF may be used; however, any suitable resistance and capacitance may be used.

A flatter AC response at low frequency improves the low frequency group-delay variation (GDV) significantly, and the improved GDV enables a reduction in BER.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

We claim:

1. An optical receiver comprising:
a photodetector configured to generate a differential input current including a first input current component and a second input current component in response to an optical signal;
a trans-impedance amplifier (TIA) comprising a first TIA section and a second TIA section, the first TIA section configured to convert the first input current component into a first input voltage component, and the second TIA section configured to convert the second input current component into a second input voltage component;
a variable gain amplifier (VGA) configured to amplify the first input voltage component and the second input voltage component to a desired output voltage forming a first output voltage component and a second output voltage component;
an AC coupler in an AC-coupled path for AC coupling the first TIA section to the photodetector; and
a DC coupler in a DC-coupled path, absent a capacitor, for DC coupling the second TIA section to the photodetector.

2. The optical receiver according to claim 1, wherein the photodetector includes an anode and a cathode; wherein the cathode is AC coupled to the first TIA section; and wherein the anode is DC coupled to the second TIA section.

3. The optical receiver according to claim 1, wherein the AC coupler comprises a coupling capacitor.

4. The optical receiver according to claim 3, wherein the coupling capacitor has a capacitance of less than 10 pF.

5. The optical receiver according to claim 3, wherein the AC coupler further comprises a coupling resistor in parallel with the coupling capacitor.

6. The optical receiver according to claim 5, wherein the coupling resistor comprises a resistance of less than 10 kΩ.

7. The optical receiver according to claim 5, wherein the AC coupler further comprises a bias voltage source connected to the coupling resistor for reverse biasing the photodetector.

8. The optical receiver according to claim 7, wherein the bias voltage source comprises a voltage of 2 to 6 volts.

9. The optical receiver according to claim 1, wherein the DC coupler comprises:
a DC cancellation circuit (DCCC) for cancelling a DC component of the second input current components or the second input voltage component by comparing the second input current component or the second input voltage component to a reference current or a reference voltage generating a comparison, and sinking the DC component of the second input current component based on the comparison.

10. The optical receiver according to claim 9, wherein the photodetector includes an anode and a cathode; wherein the cathode is AC coupled to the first TIA section; wherein the anode is DC coupled to the second TIA section; and wherein an anode voltage of the anode is set based on the reference voltage.

11. The optical receiver according to claim 9, wherein the DC cancellation circuit comprises:
a voltage comparator for comparing a sample of the second input current component or the second input voltage component to the reference voltage or current, generating the comparison; and
a current sink for sinking the DC component of the second input current component based on the comparison.

12. The optical receiver according to claim 11, wherein the reference voltage is between 0.3V and 1.5V.

13. The optical receiver according to claim 11, further comprising a replica TIA configured to generated the reference voltage.

14. The optical receiver according to claim 11, further comprising a DCCC sensing point positioned before the TIA enabling the DC cancellation circuit to sample the second input current component.

15. The optical receiver according to claim 11, further comprising a DCCC sensing point positioned after the TIA enabling the DC cancellation circuit to sample the second input voltage component.

16. The optical receiver according to claim 1, wherein the first TIA section includes a first shunt feedback impedance comprising a first feedback resistor and a second feedback resistor in parallel, and a shunt feedback capacitor in series with the first feedback resistor; and
wherein the second TIA section includes a second shunt feedback impedance comprising a third feedback resistor;
wherein each of the first feedback resistor and the second feedback resistor comprise a resistance about twice a resistance of the third feedback resistor, whereby below a desired frequency an overall resistance of the first TIA section is twice that of the second TIA section to boost gain at frequencies below the desired frequency, and whereby above the desired frequency the overall resistance of the first TIA section is equal to the second TIA section.

17. The optical receiver according to claim 16, wherein the resistance of the third feedback resistor comprises between 500Ω and 1000Ω.

18. The optical receiver according to claim 16, wherein the feedback capacitor comprises a capacitance of between 5 pF and 10 pF.
